(19) United States
(12) Patent Application Publication
(10) Pub. No.: US 2014/0079924 A1
(43) Pub. Date: Mar. 20, 2014

(54) RESIN COMPOSITION FOR PACKAGE SUBSTRATE AND PACKAGE SUBSTRATE COMPRISING CORE LAYER AND PREPREG USING THE SAME

(71) Applicant: SAMSUNG ELECTRO-MECHANICS CO., LTD., Suwon (KR)

(72) Inventors: Jin Seok MOON, Suwon (KR); Hyun Jun Lee, Suwon (KR); Jeong Kyu Lee, Suwon (KR); Seong Hyun Yoo, Suwon (KR); Keun Yong Lee, Suwon (KR)

(73) Assignee: Samsung Electro-Mechanisc Co., Ltd., Suwon (KR)

(21) Appl. No.: 13/827,527

(22) Filed: Mar. 14, 2013

(30) Foreign Application Priority Data
Sep. 19, 2012 (KR) 10-2012-0104061

(51) Int. Cl. H05K 1/03

(52) U.S. Cl. CPC H05K 1/0373
USPC 428/209; 523/400; 523/466; 523/457; 523/458; 523/445

(57) ABSTRACT

The present invention relates to a resin composition for a package substrate and a package substrate comprising a core layer and a prepreg using the same, which include a polyester amide liquid crystal oligomer, a bisphenol tetrafunctional epoxy resin, a curing agent, and an inorganic filler, wherein the bisphenol tetrafunctional epoxy resin has a viscosity of greater than 20,000 cps. According to the resin composition for a package substrate in accordance with the present invention can provide a package substrate with reduced substrate warpage by improving heat radiation characteristics of a substrate material. Further, it is possible to improve defects by reducing delamination between a chip and the substrate or occurrence of cracks of solder balls through the reduced substrate warpage characteristics.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0104061, entitled filed Sep. 19, 2012, which is hereby incorporated by reference in its entirety into this application.

### BACKGROUND OF THE INVENTION

1. Field of the Invention

The present invention relates to a resin composition for a package substrate and a package substrate comprising a core layer and a prepreg using the same.

2. Description of the Related Art

With the recent trend of miniaturization and high performance of electronic products and communication devices, as the integration of semiconductors, which are main components, increases, there is a greatly increasing demand for the semiconductors.

Among them, a package substrate is in charge of a function of electrically connecting a semiconductor chip and a mother board. With the rapid advance of improvement of mounting density of a semiconductor package due to the increase in the integration of the semiconductors, printed circuit wiring of the package substrate becomes more complicated and densified.

The package substrate chiefly comprises copper serving as circuit wiring and a polymer serving as an interlayer insulator. The warpage of the substrate is caused by a mounting temperature when mounting the semiconductor chip due to differences of thermal and mechanical characteristics from the semiconductor which is a ceramic material, thus causing occurrence of delamination between the chip and the substrate and cracks of solder balls. Due to this, the reliability of the product is badly affected, ultimately causing defects of the product.

Until now, it is known that the warpage characteristics of the substrate depend on the coefficient of thermal expansion of the material, but heat radiation characteristics related to thermal stress are also recognized as an important factor that determines the warpage behavior of the substrate.

A material and a manufacturing method of most of conventional package substrates are as in FIG. 1.

An epoxy insulating material formed by vertically laminating copper foils is used as a core 10, and a through hole 20, which conducts upper and lower layers of the core 10, is formed by laser hole processing. In a process of forming a conductor, a through hole conductor is formed by performing electrolytic copper plating after electroless copper plating to fill the entire through hole of the core insulating material 10 and conductor layers are formed on and under the core insulating material 10.

A circuit pattern 30 is formed on the conductor layer, and the epoxy insulating material 10 is laminated on and under the circuit pattern 30 together with a copper layer. After processing a laser hole in the laminated insulating material layer, electroless copper plating and electrolytic copper plating are performed to achieve interlayer conduction with the internal circuit pattern layer.

Further, after forming circuit patterns on the upper and lower copper layers, a solder resist layer 40 is formed and a bump pad portion 50 is formed.

However, in the package substrate that forms an insulating layer with an epoxy material like this, the warpage of the substrate occurs due to heat radiation characteristics after mounting a semiconductor chip, thus causing delamination between the chip and the substrate or cracks of solder balls.

### RELATED ART DOCUMENT

### Patent Document

Patent Document 1: Korean Patent Laid-Open Publication No. 2010-75383

### SUMMARY OF THE INVENTION

The present invention has been invented in order to overcome the above-described problems and it is, therefore, an object of the present invention to provide a resin composition for a package substrate that can overcome warpage of a package substrate by improving heat radiation characteristics.

Further, it is another object of the present invention to provide a resin composition as a core insulating material and a prepreg of a package substrate.

In accordance with one aspect of the present invention to achieve the object, there is provided a resin composition for a package substrate including: a polyester amide liquid crystal oligomer, a bisphenol tetrafunctional epoxy resin, a curing agent, and an inorganic filler.

It is preferred that the bisphenol tetrafunctional epoxy resin has a viscosity of greater than 20,000 cps.

It is preferred that the polyester amide liquid crystal oligomer is represented by the following chemical formula 1 and has a viscosity in the range of 800 to 1000 cps.

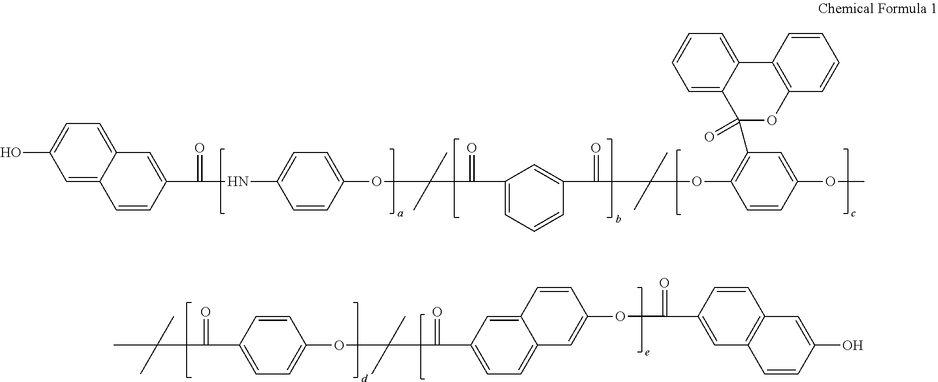

In the chemical formula 1, a, b, c, d, e are repeating units, a is an integer from 13 to 26, b is an integer from 13 to 26, c is an integer from 9 to 21, d is an integer from 10 to 30, and e is an integer from 10 to 30.

The bisphenol tetrafunctional epoxy resin may be at least one selected from the group consisting of a bisphenol A epoxy resin, a bisphenol F epoxy resin, a bisphenol S epoxy resin, a naphthalene epoxy resin, a rubber-modified epoxy resin, and a phosphorus epoxy resin.

The curing agent may be at least one selected from the group consisting of 2-methylimidazole, 2-phenylimidazole, 2-phenyl-4-phenyl imidazole, bis(2-ethyl-4-methylimidazole), 2-phenyl-4-methyl-5-hydroxylmethyl limidazole, 2-phenyl-4,5-dihydroxymethyl imidazole, triazine-added imidazole, anhydrous methyl nadic acid, dicyandiamide, phthalic anhydride, tetrahydrophthalic anhydride, methylbutyltetrahydrophthalic anhydride, hexahydrophthalic anhydride, methylhydrophthalic anhydride, trimellitic acid anhydride, pyromellitic acid anhydride, and benzophenonetetracarboxylic acid anhydride.

The inorganic filler may be at least one selected from the group consisting of natural silica, fused silica, amorphous silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, boron nitride (BN), silicon nitride, silicon oxide, aluminum titanate, barium titanate, barium strontium titanate, aluminum oxide, alumina, clay, kaoline, talc, calcined clay, calcined kaoline, calcined talc, mica, short glass fibers, and mixtures thereof.

The resin composition may include the polyester amide liquid crystal oligomer 10 to 30 wt %, the bisphenol tetrafunctional epoxy resin 5 to 20 wt %, the curing agent 0.05 to 0.2 wt %, and the inorganic filler 50 to 90 wt %.

It is preferred that the resin composition has a viscosity of 700 to 1500 cps.

Further, in accordance with another aspect of the present invention to achieve the object, there is provided a package substrate using a resin composition including a polyester amide liquid crystal oligomer, a bisphenol tetrafunctional epoxy resin, a curing agent, and an inorganic filler as a core insulating material and including circuit patterns formed on the core insulating material.

The core insulating material may be a copper clad laminate (CCL) formed by vertically laminating copper foils or a prepreg.

It is preferred that a thickness of the CCL is less than 300 μm.

It is preferred that a coefficient of thermal expansion (CTE) of the CCL is less than 5.0 ppm/° C.

It is preferred that a thermal conductivity of the CCL is greater than 0.55 W/mk.

Further, in accordance with an embodiment of the present invention, the package substrate may include a prepreg for insulation between the circuit patterns.

It is preferred that the prepreg is formed of a resin composition including a polyester amide liquid crystal oligomer, a bisphenol tetrafunctional epoxy resin, a curing agent, and an inorganic filler.

It is preferred that a thickness of the prepreg is less than 50 μm.

It is preferred that a CTE of the prepreg is less than 5.0 ppm/° C.

It is preferred that a thermal conductivity of the prepreg is greater than 0.55 W/mk.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 shows a structure of a conventional package substrate; and

FIG. 2 shows a functional group behavior theory of a liquid crystal oligomer in a thermal conduction condition.

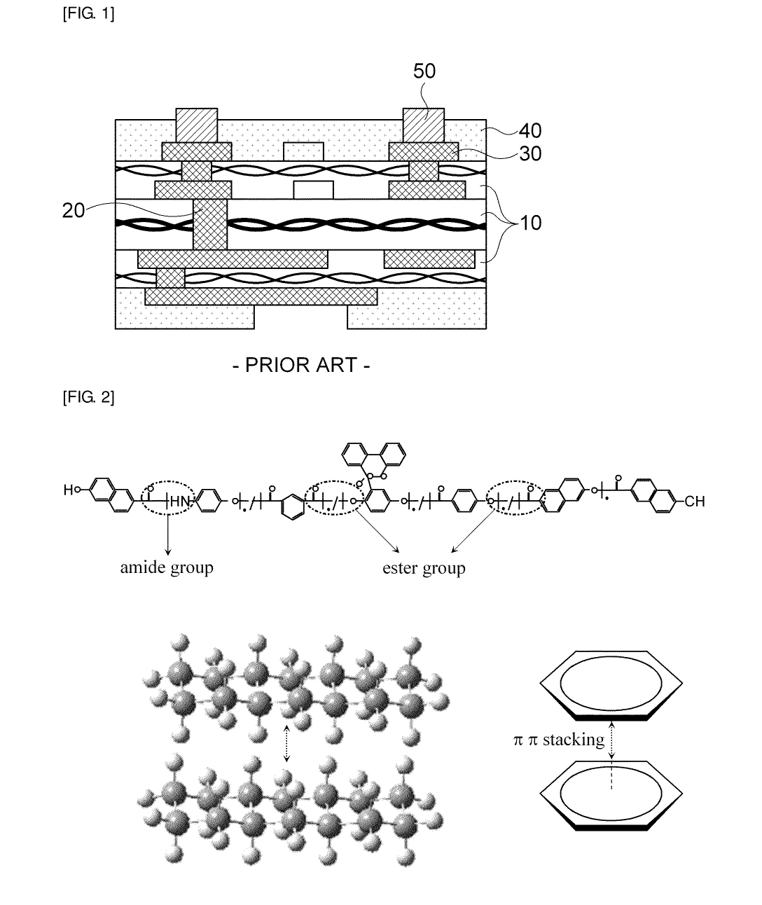

### DETAILED DESCRIPTION OF THE PREFERABLE EMBODIMENTS

Hereinafter, the present invention will be described in detail.

Terms used herein are provided to explain embodiments, not limiting the present invention. Throughout this specification, the singular form includes the plural form unless the context clearly indicates otherwise. Further, terms “comprises” and/or “comprising” used herein specify the existence of described shapes, numbers, steps, operations, members, elements, and/or groups thereof, but do not preclude the existence or addition of one or more other shapes, numbers, operations, members, elements, and/or groups thereof.

The present invention relates to a composition that can be used as a core insulating material of a package substrate or an insulating prepreg of a package substrate.

An insulating composition of a package substrate in accordance with the present invention includes a polyester amide liquid crystal oligomer, a bisphenol tetrafunctional epoxy resin, a curing agent, and an inorganic filler and is characterized by particularly using the bisphenol tetrafunctional epoxy resin having a viscosity of greater than 20,000 cps.

In the insulating composition used as a core insulating material in accordance with the present invention, it is most preferred to use the bisphenol tetrafunctional epoxy resin as an epoxy resin in terms of manufacturing efficiency of a package substrate material and excellent adhesive strength with a metal surface.

The viscosity of the bisphenol tetrafunctional epoxy resin is greater than 20,000 cps, preferably 20,000 to 25,000 cps. When the viscosity of the bisphenol tetrafunctional epoxy resin of the present invention is less than 20,000 cps, it is not preferred since it is not possible to manufacture a package substrate having a low coefficient of thermal expansion and heat radiation characteristics desired in the present invention.

For a concrete example, the bisphenol tetrafunctional epoxy resin may be at least one selected from the group consisting of a bisphenol A epoxy resin, a bisphenol F epoxy resin, and a bisphenol S epoxy resin. Among them, a bisphenol A epoxy resin is most preferable.

Particularly, it is preferred that the bisphenol epoxy resin has tetrafunctionality to improve reactivity with the polyester amide liquid crystal oligomer and thus increase the degree of curing. It is preferred that the functional group is an epoxide group.

In the insulating composition of the present invention, the bisphenol tetrafunctional epoxy resin is included in an amount of 5 to 20 wt %. When the content of the bisphenol tetrafunctional epoxy resin is less than 5 wt %, it is not preferred since a peel strength value, which is a major characteristic of a substrate material, is reduced, and when exceeding 20 wt %, it is not preferred since the content of the polyester amide liquid crystal oligomer in the composition is relatively reduced and crystallinity and density due to rearrangement between molecular chains are reduced, thus being disadvantageous to thermal conductivity.

Further, it is preferred that the curing agent of the epoxy resin is an imidazole curing agent such as 2-methylimidazole, 2-phenylimidazole, 2-phenyl-4-phenyl imidazole, bis(2-ethyl-4-methylimidazole), 2-phenyl-4-methyl-5-hydroxylmethyl limidazole, 2-phenyl-4,5-dihydroxymethyl imidazole, or triazine-added imidazole; and an acid anhydride curing agent such as anhydrous methyl nadic acid, dicyandiamide, phthalic anhydride, tetrahydrophthalic anhydride, methylbutyltetrahydrophthalic anhydride, hexahydrophthalic anhydride, methylhydrophthalic anhydride, trimellitic acid anhydride, pyromellitic acid anhydride, or benzophenonetetracarboxylic acid anhydride.

The curing agent is included in the insulating composition in an amount of 0.05 to 0.2 wt % to maintain characteristics such as glass transition temperature, modulus, and coefficient of thermal expansion at a desired level due to appropriate curing density.

Further, the polyester amide liquid crystal oligomer in the insulating composition of the present invention is represented by the following chemical formula 1 and has a structure including hydroxyl groups connected to both terminals and polar groups such as ester and amide groups in a main chain.

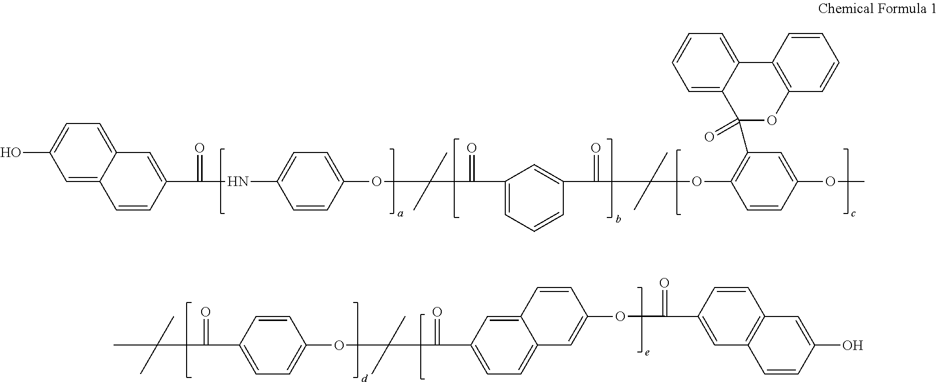

In the chemical formula 1, a, b, c, d, e are repeating units, a is an integer from 13 to 26, b is an integer from 13 to 26, c is an integer from 9 to 21, d is an integer from 10 to 30, and e is an integer from 10 to 30.

It is preferred that a number average molecular weight of the liquid crystal oligomer in accordance with the present invention is 3000 to 5000 g/mol to have a proper crosslinking density, secure heat resistance, and have high solubility in a solvent.

It is preferred that a viscosity of the polyester amide liquid crystal oligomer is in the range of 800 to 1000 cps. When less than 800 cps, it is not possible to manufacture a material with a desired thickness and defects such as non-uniformity of thickness occur since impregnation workability is deteriorated due to high flowability and the oligomer easily flows. Further, when exceeding 1000 cps, defects such as a void of the material occur since it can't fill a proper capacity due to low flowability, thus deteriorating heat radiation characteristics.

In the insulating composition of the present invention, the polyester amide liquid crystal oligomer is included in an amount of 10 to 30 wt %. When the content of the liquid crystal oligomer is less than 10 wt %, it is not preferred since it is disadvantageous to thermal conductivity due to deterioration of crystallinity and density by rearrangement between molecular chains of the insulating material, and when exceeding 30 wt %, it is not preferred since the content of the epoxy resin is relatively reduced and thus a peel strength value, which is a major characteristic of a substrate material, is reduced.

The inorganic filler may be at least one selected from the group consisting of natural silica, fused silica, amorphous silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, boron nitride (BN), silicon nitride, silicon oxide, aluminum titanate, barium titanate, barium strontium titanate, aluminum oxide, alumina, clay, kaoline, talc, calcined clay, calcined kaoline, calcined talc, mica, short glass fibers, and mixtures thereof. Among them, silica can be preferably used.

In the insulating composition of the present invention, the inorganic filler is included in an amount of 50 to 90 wt %. When less than 50 wt %, it is not preferred since a thermal conductivity value is reduced, and when exceeding 90 wt %, it is not preferred due to a difficulty in filling.

It is preferred that a viscosity of the insulating composition including the above components in accordance with the present invention is 700 to 1500 cps in terms of impregnation workability, uniformity of material thickness, and improvement of heat radiation characteristics.

Further, it is preferred that the viscosity of the insulating composition except the inorganic filler is 1000 to 2000 cps. The viscosity of the insulating composition may be adjusted according to the content of a solvent and a proper impregnation viscosity may be adjusted by adjusting the amount of the solvent. It is preferred that the content of the non-volatile component except the solvent is 30 to 70 wt %.

In addition, unless deteriorating the desired properties, the insulating composition of the present invention may further include other curing agent, curing accelerator, leveling agent, flame retardant, etc. according to the need.

In accordance with an embodiment of the present invention, a package substrate using the insulating composition as a core insulating material and including circuit patterns formed on the core insulating material is provided.

The core insulating material may be a copper clad laminate (CCL) formed by vertically laminating copper foils or a prepreg.

In accordance with another embodiment, a package substrate using the insulating composition as a core insulating material and including circuit patterns formed on the core insulating material and a prepreg for insulation between the circuit patterns.

That is, the insulating composition in accordance with the present invention can be used as a prepreg for insulation between circuit patterns of a package substrate as well as being used in the form of a CCL or a prepreg as a core insulating material of the package substrate.

Further, the core insulating material of the present invention may have a composite form prepared by impregnating a reinforcing material in the insulating composition.

For a concrete example, the reinforcing material may be woven glass cloth, woven alumina glass fibers, glass fiber non-woven fabrics, cellulose non-woven fabrics, woven carbon fibers, polymer fabrics, etc. Further, the reinforcing material may be at least one selected from the group consisting of glass fibers, silica glass fibers, carbon fibers, alumina fibers, silicon carbide fibers, asbestos, rock wool, mineral wool, gypsum whisker, and woven fabrics or non-woven fabrics thereof, aromatic polyamide fibers, polyimide fibers, liquid crystal polyester, polyester fibers, fluoride fibers, polybenzoxazole fibers, glass fibers with polyamide fibers, glass fibers with carbon fibers, glass fibers with polyimide fibers, glass fibers with aromatic polyester, glass paper, mica paper, alumina paper, kraft paper, cotton paper, paper-glass combined paper, etc. Among them, woven glass cloth using E-glass, T-glass, S-glass, and L-glass yarn is most preferable.

The package substrate in accordance with the present invention may be manufactured by forming a via-hole for vertical conduction in a core insulating material of a package substrate using the insulating composition, filling the via-hole through electroless copper plating and electrolytic copper plating, and forming upper and lower circuit layers.

Further, the package substrate in accordance with the present invention may be manufactured by forming a circuit layer on a core insulating material of a package substrate using the insulating composition, vertically laminating an insulating prepreg using the insulating composition, forming a via-hole, filling the via-hole through electroless copper plating and electrolytic copper plating, and forming upper and lower circuit layers.

Further, the package substrate using the insulating composition of the present invention may be formed in a multilayer structure consisting of more than two layers and the number of layers may be properly selected according to a predetermined purpose.

In the present invention, the processes of laminating, forming a via-hole, and forming a circuit layer can be repeatedly performed.

The core insulating material may be a copper clad laminate (CCL) formed by vertically laminating copper foils or a prepreg.

In the package substrate of the present invention, when the core insulating material is a CCL, it is preferred that the CCL is formed with a thickness of less than 300 μm in terms of implementation of a thin package substrate and reduction of warpage of the substrate due to high heat radiation characteristics in the thin package substrate. Therefore, it is preferred that a coefficient of thermal expansion (CTE) of the CCL is less than 5.0 ppm/° C. and a thermal conductivity thereof is greater than 0.55 W/mk.

Further, in the package substrate of the present invention, when the core insulating material is a prepreg or used as an insulating prepreg of the circuit pattern, it is preferred that a thickness of the prepreg is less than 50 μm in terms of implementation of a thin package substrate and reduction of warpage of the substrate due to high heat radiation characteristics in the thin package substrate.

Further, in the package substrate of the present invention, when the core insulating material is a prepreg or used as an insulating prepreg of the circuit pattern, it is preferred that a CTE of the prepreg is less than 10.0 ppm/° C. and a thermal conductivity thereof is greater than 0.35 W/mk.

Further, these substrate warpage characteristics have more influence on heat radiation characteristics in a thermal conduction condition than an isothermal condition, and the thermal conductivity of the package substrate in accordance with the present invention is 15 W/mk in the range of 10 to 30° C. and 13 W/mk in the range of 100 to 130° C.

Hereinafter, preferred embodiments of the present invention will be described in detail. The following embodiments merely illustrate the present invention, and it should not be interpreted that the scope of the present invention is limited to the following embodiments. Further, although certain compounds are used in the following embodiments, it is apparent to those skilled in the art that equal or similar effects are shown even when using their equivalents.

### Embodiment 1

218.26 g (2.0 mol) of 4-aminophenol, 415.33 g (2.5 mol) of isophthalic acid, 276.24 g (2.0 mol) of 4-hydroxybenzoic acid, 282.27 g (1.5 mol) of 6-hydroxy-2-naphthoic acid, 648.54 g (2.0 mol) of DOPO-HG, and 1531.35 g (15.0 mol) of acetic acid anhydride are added to a 10˜20 L glass reactor. After sufficiently substituting the inside of the reactor with nitrogen gas, a temperature inside the reactor is raised to a temperature of 230° C. under a flow of nitrogen gas, and the mixture is refluxed for 4 hours while maintaining the temperature inside the reactor at the raised temperature.

After additionally adding 188.18 g (1.0 mol) of end-capping 6-hydroxy-2-naphthoic acid, acetic acid, which is a reaction byproduct, and unreacted acetic acid anhydride are removed to obtain a polyester amide liquid crystal oligomer. A number average molecular weight of the liquid crystal oligomer is measured as 3500 to 5000 g/mol and a viscosity thereof is measured as 850 cps.

A composition (viscosity 800 cps) including the polyester amide liquid crystal oligomer 24 wt %, a bisphenol F tetrafunctional epoxy resin (viscosity 20,000 cps) 16 wt %, dicyandiamide 0.16 wt % as a curing agent, and silica 60 wt % as an inorganic filler is prepared.

A prepreg type substrate material is prepared by impregnating the insulating composition into woven glass cloth, and a thickness thereof is 40 μm.

A core insulating material (CCL) is prepared by vertically laminating 12 μm copper foils, and a thickness thereof is 100 μm.

### Comparative Example 1

Except for using an insulating composition consisting of an epoxy resin (novolac epoxy resin) 40 wt % and an inorganic filler (silica) 60 wt % as a core insulating material and an insulating prepreg of a substrate, a package substrate material is prepared by the same process as the embodiment 1.

### Experimental Example 1

Thermal conductivity, coefficient of thermal expansion, and substrate warpage characteristics of the package substrate materials in accordance with the embodiment 1 and the comparative example 1 are measured, and the results thereof are shown in the following table 1.

TABLE 1

| Characteristics | Comparative Example 1 | Embodiment 1 |
|---|---|---|
| Coefficient of Thermal | 5.4 | 4.6 |
| Expansion (CTE, ppm/° C.) | | |
| Thermal Conductivity (W/mk) | 12 | 15 |
| Substrate Warpage (μm) | −47~127 | −25~68 |

As in the results of the table 1, the heat radiation characteristics of the package substrate in accordance with the embodiment 1 prepared by adding the liquid crystal oligomer, the bisphenol tetrafunctional epoxy resin, and the silica inorganic filler are greater than 15 Kw which are improved by more than 25%, and the warpage region thereof is −25 to 68 μm, that is, the substrate warpage is reduced by 47%. Further, the CTE thereof is measured as lower than the comparative example 1.

The theory that the heat radiation characteristics of the package substrate influence the substrate warpage like this, as shown in FIG. 2, is that the polyester amide liquid crystal oligomer included in the insulating composition of the package substrate of the present invention has low warpage characteristics by a structure advantageous to heat radiation since crystallinity and density due to rearrangement between molecular chains are increased by stacking between aromatic structures such as a phenyl group and a naphthalene group and interaction of polar groups such as an ester group and an amide group in the molecular chains.

The resin composition for a package substrate in accordance with the present invention can provide a package substrate with reduced substrate warpage by improving heat radiation characteristics of a substrate material. Further, it is possible to improve defects by reducing delamination between a chip and the substrate or occurrence of cracks of solder balls through the reduced substrate warpage characteristics.

What is claimed is:

1. A resin composition for a package substrate, comprising:
a polyester amide liquid crystal oligomer, a bisphenol tetrafunctional epoxy resin, a curing agent, and an inorganic filler.

2. The resin composition for a package substrate according to claim 1, wherein the bisphenol tetrafunctional epoxy resin has a viscosity of greater than 20,000 cps.

3. The resin composition for a package substrate according to claim 1, wherein the bisphenol tetrafunctional epoxy resin is at least one selected from the group consisting of a bisphenol A epoxy resin, a bisphenol F epoxy resin, a bisphenol S epoxy resin, a naphthalene epoxy resin, a rubber-modified epoxy resin, and a phosphorus epoxy resin.

4. The resin composition for a package substrate according to claim 1, wherein the polyester amide liquid crystal oligomer is represented by the following chemical formula 1: 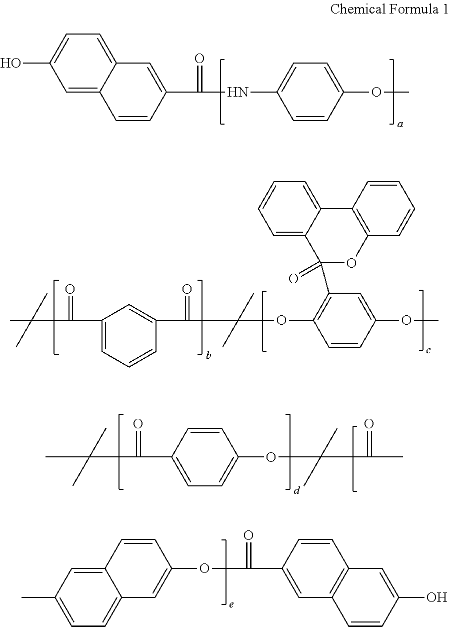
In the chemical formula 1, a, b, c, d, e are repeating units, a is an integer from 13 to 26, b is an integer from 13 to 26, c is an integer from 9 to 21, d is an integer from 10 to 30, and e is an integer from 10 to 30.

5. The resin composition for a package substrate according to claim 4, wherein the polyester amide liquid crystal oligomer represented by the chemical formula 1 has a viscosity in the range of 800 to 1000 cps.

6. The resin composition for a package substrate according to claim 1, wherein the curing agent is at least one selected from the group consisting of 2-methylimidazole, 2-phenylimidazole, 2-phenyl-4-phenyl imidazole, bis(2-ethyl-4-methylimidazole), 2-phenyl-4-methyl-5-hydroxylmethyl limidazole, 2-phenyl-4,5-dihydroxymethyl imidazole, triazine-added imidazole, anhydrous methyl nadic acid, dicyandiamide, phthalic anhydride, tetrahydrophthalic anhydride, methylbutyltetrahydrophthalic anhydride, hexahydrophthalic anhydride, methylhydrophthalic anhydride, trimellitic acid anhydride, pyromellitic acid anhydride, and benzophenonetetracarboxylic acid anhydride.

7. The resin composition for a package substrate according to claim 1, wherein the inorganic filler is at least one selected from the group consisting of natural silica, fused silica, amorphous silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, boron nitride (BN), silicon nitride, silicon oxide, aluminum titanate, barium titanate, barium strontium titanate, aluminum oxide, alumina, clay, kaoline, talc, calcined clay, calcined kaoline, calcined talc, mica, short glass fibers, and mixtures thereof.

8. The resin composition for a package substrate according to claim 1, wherein the resin composition comprises the polyester amide liquid crystal oligomer 10 to 30 wt %, the bisphenol tetrafunctional epoxy resin 5 to 20 wt %, the curing agent 0.05 to 0.2 wt %, and the inorganic filler 50 to 90 wt %.

9. The resin composition for a package substrate according to claim 1, wherein the resin composition has a viscosity of 700 to 1500 cps.

10. A package substrate using a resin composition according to claim 1 as a core insulating material and comprising circuit patterns formed on the core insulating material.

11. The package substrate according to claim 10, wherein the core insulating material is a copper clad laminate (CCL) formed by vertically laminating copper foils or a prepreg.

12. The package substrate according to claim 11, wherein a thickness of the CCL is less than 300 μm.

13. The package substrate according to claim 11, wherein a coefficient of thermal expansion (CTE) of the CCL is less than 5.0 ppm/° C.

14. The package substrate according to claim 11, wherein a thermal conductivity of the CCL is greater than 0.55 W/mk.

15. The package substrate according to claim 11, wherein a thickness of the prepreg is less than 50 μm.

16. The package substrate according to claim 11, wherein a CTE of the prepreg is less than 5.0 ppm/° C.

17. The package substrate according to claim 11, wherein a thermal conductivity of the prepreg is greater than 0.55 W/mk.

18. The package substrate according to claim 10, additionally comprising a prepreg for insulation between the circuit patterns.

19. The package substrate according to claim 18, wherein the prepreg is a resin composition according to claim 1.

20. The package substrate according to claim 18, wherein a thickness of the prepreg is less than 50 μm.

21. The package substrate according to claim 18, wherein a CTE of the prepreg is less than 5.0 ppm/° C.

22. The package substrate according to claim 18, wherein a thermal conductivity of the prepreg is greater than 0.55 W/mk.
